(19) United States
(12) Patent Application Publication
(10) Pub. No.: US 2017/0302103 A1
(43) Pub. Date: Oct. 19, 2017

(54) AUXILIARY POWER FOR LUMINIARE NODE CONTROLLERS

(71) Applicant: General Electric Company, Schenectady, NY (US)

(72) Inventor: Himamshu V. PRASAD, Cleveland, OH (US)

(21) Appl. No.: 15/480,399

(22) Filed: Apr. 6, 2017

Related U.S. Application Data
(60) Provisional application No. 62/324,048, filed on Apr. 18, 2016.

(51) Int. Cl. H02J 9/06; H05B 33/08; H02J 3/38; G05B 15/02; H05B 37/02; G01R 22/06

(52) U.S. Cl. CPC H02J 9/06; H05B 37/02; H05B 33/0809; G01R 22/061; H02J 3/383; G05B 15/02; H02J 3/386

(57) ABSTRACT

Provided is a control system electrically coupled to a luminaire. The control system includes a processor for facilitating (i) luminaire control and (ii) performance of a number of advanced functions. The processor is configured to receive power from at least two power sources, wherein one of the power sources is configured to provide power responsive to a level of power provided by the other power source.

### CROSS-REFERENCE TO RELATED APPLICATION

This application claims the benefit of U.S. Provisional Application No. 62/324,048, filed Apr. 18, 2016, which is incorporated by reference herein, in its entirety.

### TECHNICAL FIELD

The present invention generally relates to providing power to devices connected to light poles. More particularly, the present invention relates to providing auxiliary power to the lighting fixture communications nodes in the absence of alternating current (AC) line power being supplied to the poles.

### BACKGROUND

As the demand for intelligent lighting fixtures expands, so does the list of advanced functions being added to these fixtures. The heart of an intelligent lighting fixture, such as a luminaire, is it's communications node. The advanced functions can include online monitoring of luminaire data, such as lumen output, calibration data, power delivery, metering data, ON & OFF schedules, maintenance records, location data, etc. Other advanced functions include providing support or control of nearby devices, such as transferring and/or receiving data from parking meters to detect presence of absence of parked cars.

These advancements are not limited to applicability to lighting fixtures or functions related to vehicles. For example, other advanced functions can include monitoring, controlling, and processing data from cameras and/or microphones, for security or pedestrian traffic management applications. Yet other of the functions can include, but are not limited to, moderating environmental conditions, such as temperature, humidity, pressure etc. These new functions, or functionalities, are provided via the communications nodes, or node controllers (i.e., node), coupled to the intelligent fixture.

As understood by those of skill in the art, availability of continuous power to the node is critical for the various applications noted above. The node could be for lighting control, for the non-lighting applications, and/or other intelligent cities related applications such as environmental applications, health applications, transportation and traffic management functions, governance, water, farming etc.

It is common in many parts of the world, including the United States and Europe, to interrupt power to light poles, to which the intelligent fixtures are attached, during daylight hours. Unfortunately, this interruption will render the node's non-functional (e.g., non-lighting related) activities unachievable during the day.

### SUMMARY OF THE EMBODIMENTS

Given the aforementioned deficiencies, a need exists for alternative means of providing power to the node to maintain function when power to the pole is interrupted. The embodiments featured herein mitigate the above-noted deficiencies. Specifically, the embodiments confer the ability to provide power to the node, for example, during daylight hours. This additional power permits performance of the additional functions capable of being performed by the node by providing continuous power thereto.

Under certain circumstances, an embodiment of the present invention provides a control system electrically coupled to a luminaire. The control system includes a processor for facilitating (i) luminaire control and (ii) performance of a number of advanced functions. The processor is configured to receive power from at least two power sources, wherein one of the power sources is configured to provide power responsive to a level of power provided by the other power source.

Additional features, modes of operations, advantages, and other aspects of various embodiments are described below with reference to the accompanying drawings. It is noted that the present disclosure is not limited to the specific embodiments described herein. These embodiments are presented for illustrative purposes only. Additional embodiments, or modifications of the embodiments disclosed, will be readily apparent to persons skilled in the relevant art(s) based on the teachings provided.

### DESCRIPTION OF THE DRAWINGS

Illustrative embodiments may take form in various components and arrangements of components. Illustrative embodiments are shown in the accompanying drawings, throughout which like reference numerals may indicate corresponding or similar parts in the various drawings. The drawings are only for purposes of illustrating the embodiments and are not to be construed as limiting the disclosure. Given the following enabling description of the drawings, the novel aspects of the present disclosure should become evident to a person of ordinary skill in the relevant art(s).

FIG. 1 is an illustration of light poles and luminaires in which embodiments of the invention may be practiced.

FIG. 2 is a more detailed illustration of the luminaire depicted in FIG. 1.

FIG. 3 is an exemplary illustration of alternative powers sources, in accordance with the embodiments.

FIG. 4 is a tabular illustration of off-grid controller power scenarios, according to the embodiments.

FIG. 5 is a tabular illustration of on-grid controller power scenarios, according to the embodiments.

FIG. 6 is an illustration of a non-generic computer system configured for executing aspects of the embodiments.

### DETAILED DESCRIPTION OF THE EMBODIMENTS

While the illustrative embodiments are described herein for particular applications, it should be understood that the present disclosure is not limited thereto. Those skilled in the art and with access to the teachings provided herein will recognize additional applications, modifications, and embodiments within the scope thereof and additional fields in which the present disclosure would be of significant utility.

As noted above, in the United States, and in most European countries, power to light poles is turned off during the day. However, computers, cameras, sensors, and other devices associated with intelligent fixtures, must also function during daylight hours. Since these functions are associated with applications such as parking optimization, traffic management etc., it's desirable that they receive uninterrupted power. When power is interrupted, all node functionalities are lost. Embodiments of the present invention present an approach for providing auxiliary power to light poles during daylight hours, or other times when standard AC line power is interrupted.

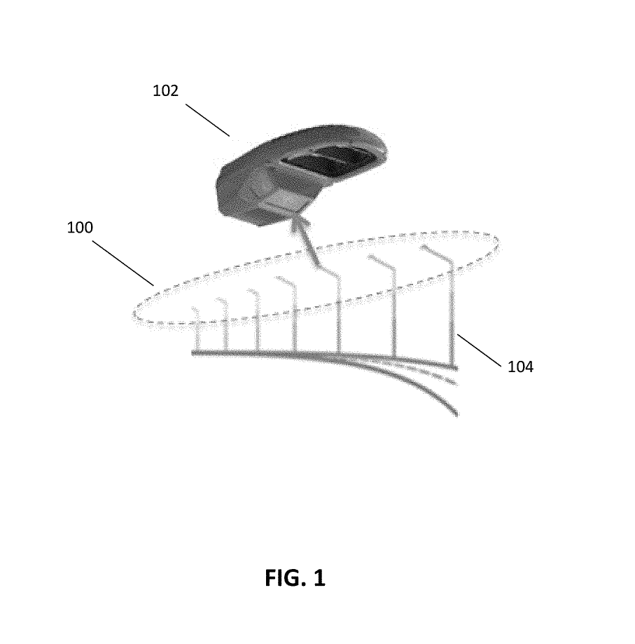

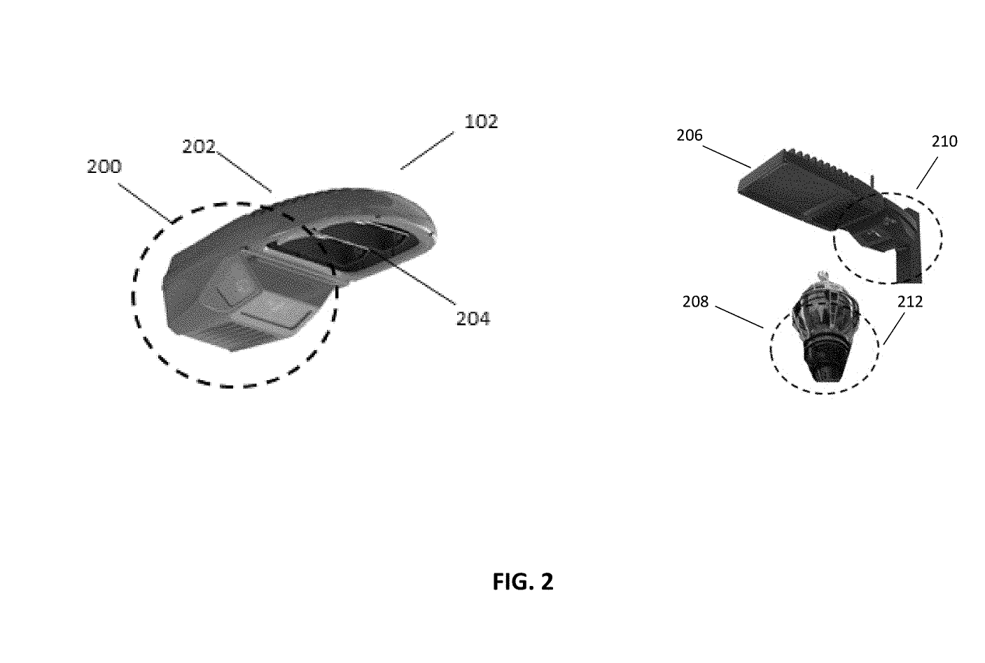

FIG. 1 is an illustration of lighting system 100 including a number of light emitting diode (LED) luminaires 102 affixed to a light poles 104, in accordance with the embodiments. In FIG. 1, as understood by those of skill in the art, AC power is provided to the luminaires 102, via the poles 104, to energize the LEDs, and other electrical devices, therewithin. FIG. 2 is a more detailed view of the luminaire 102 depicted in FIG. 1, along with alternatively styled lighting fixtures.

As illustrated in FIG. 2, the luminaire 102 includes a node controller (i.e., node) 200 coupled to a luminaire 202. Among other components, the luminaire fixture 202 includes a cavity in which a lighting module 204 is mounted to a light receptacle (not shown). The lighting module 204 houses light sources, such as LEDs. The cavity can be covered with a transparent glass (not shown) that protects the light sources from the elements. FIG. 2 also depicts alternatively styled lighting fixtures 206 and 208, including nodes 210 and 212, respectively.

By way of example, nodes, such as the node 200, are programmable devices, or can be programmable modules located in a much larger device. Among other things, the node 200 controls operation of the luminaire fixture 202. Additionally, the node 200 can include a photo-electric element configured to sense ambient light and provide dimming commands to the luminaire, based on predetermined ambient light level thresholds.

The node 200 can also include one or more cameras for recording video or images, microphones, or can facilitate access to a communications network, such as Wi-Fi. Alternatively, or additionally, the node 200 can include sensors for capturing data associated with environmental conditions such as temperature, humidity, pressure, and the like.

Standard operating protocols mandate that power to the light pole 104 be interrupted during sunlight, when the luminaire 102 is not needed for lighting. Interruption to power provided to the light pole 104 renders the node 200 inoperable and unable to support the non-functional activities noted earlier. In accordance with the embodiments, power to the light pole can be provided via alternative sources such as solar panels, battery packs, mini wind turbines, and the like.

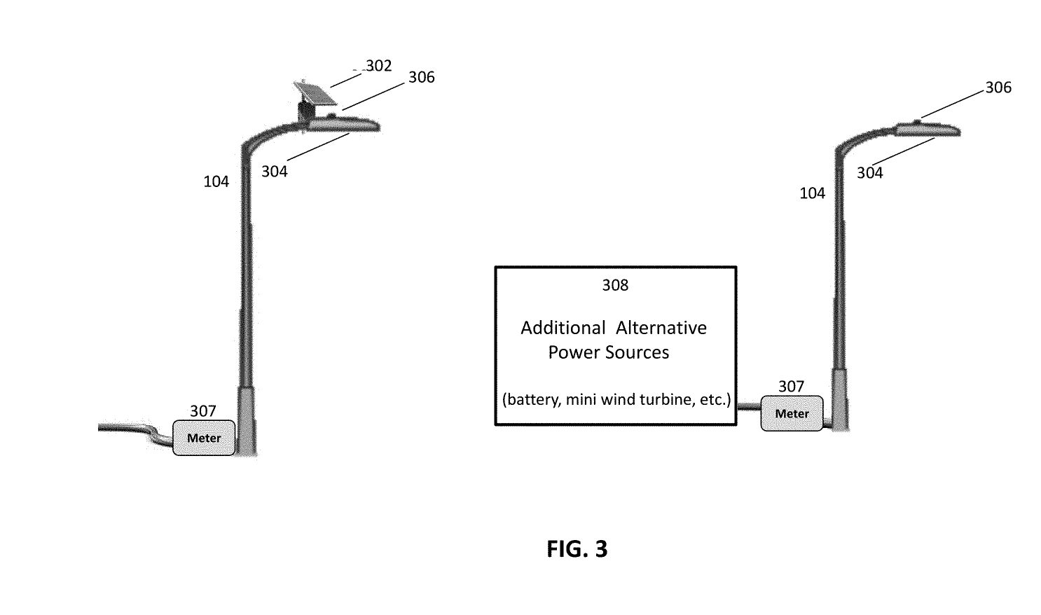

FIG. 3 depicts a sample of auxiliary power sources capable of augmenting or replacing AC line power provided to the pole, in accordance with the embodiments. The light pole 104 can receive power via solar panels 302 coupled to the pole 104. In FIG. 3, the solar panel 302 provides power to the luminaire 304 and to a node, such as a wireless node 306. Power provided via the solar panel 302 could also be combined with AC line power supplied from a power grid. In this scenario, and for cost accounting purposes, a meter 307 can be used to measure the supplied AC line power and/or the power provided from the solar panel 302.

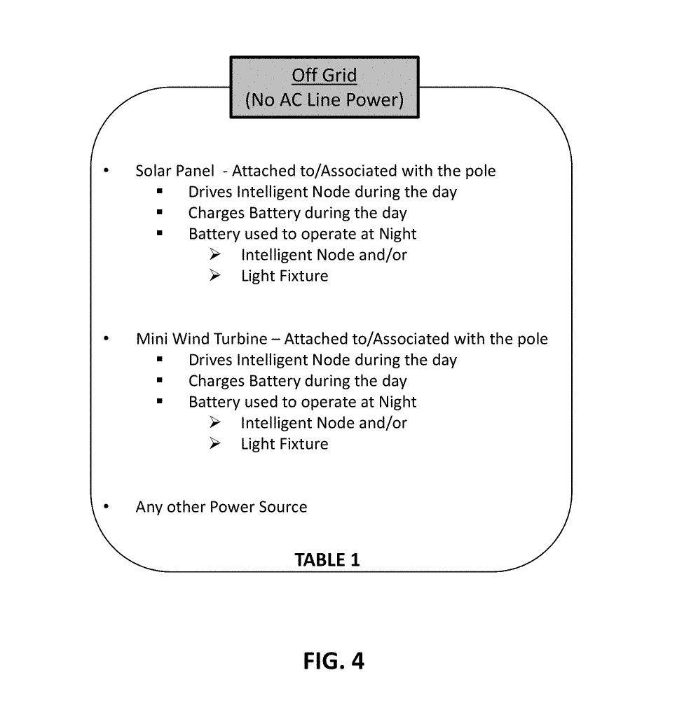

Alternatively, additional alternative power sources 308, such as batteries, mini wind turbines etc. may also provide power to luminaire 304 and/or the node 306. For purposes of illustration, and as described herein, FIG. 4 depicts example scenarios in which embodiments of the present invention may be used to provide auxiliary power to light poles.

In FIG. 4, Table 1 depicts an off grid scenario. In the Table 1 scenario, the light pole 104 is completely devoid of an AC power source. That is, the light pole 104 is not connected to an AC power line. This scenario could be consistent with the pole 104 being deployed or used in a remote location. In Table 1, a power source, such as the solar panel 302 (see FIG. 3), can be used in a standalone fashion, or in conjunction with a battery pack, and/or wind turbine.

During use in a Table 1 scenario, the solar panel 302 can be attached to the pole 104, and used to drive the node 306. It can also charge the batteries (not shown) during the day. Once charged, the batteries can power the node 306 and/or lighting fixture 304 at night. Alternatively, a mini wind turbine could be attached or associated with the pole 104.

An alternative power source 308, such as a mini wind turbine, electrically coupled to the pole 104, could also drive the node 306 and charge the batteries during the day. As in the case above with the solar panel 302, when charged, the batteries can power the node 306 and/or the lighting fixture 304 at night. However, and as understood by those of skill in the art, the alternative power sources (e.g., batteries and solar panels) can only provide power for a predetermined amount of time (e.g., 6 hours, 12 hours etc.). After lapse of this predetermined amount of time, the amount of provided power may begin to diminish.

As the amount of provided auxiliary power begins to diminish, a control scheme may be necessary to regulate or prioritize the functions performed by the control node 306. By way of example, the control node 306 may be capable of performing X number of advanced functions under full power. However, at 75% of full power, as would be the case when the auxiliary power begins to diminish, the control node 306 may be capable of only performing X-Y number of advanced functions. Such a scheme would enable the control node 306 to perform its functions any manner responsive to the provided power, allowing the control node 306 to gracefully degrade during periods of limited power.

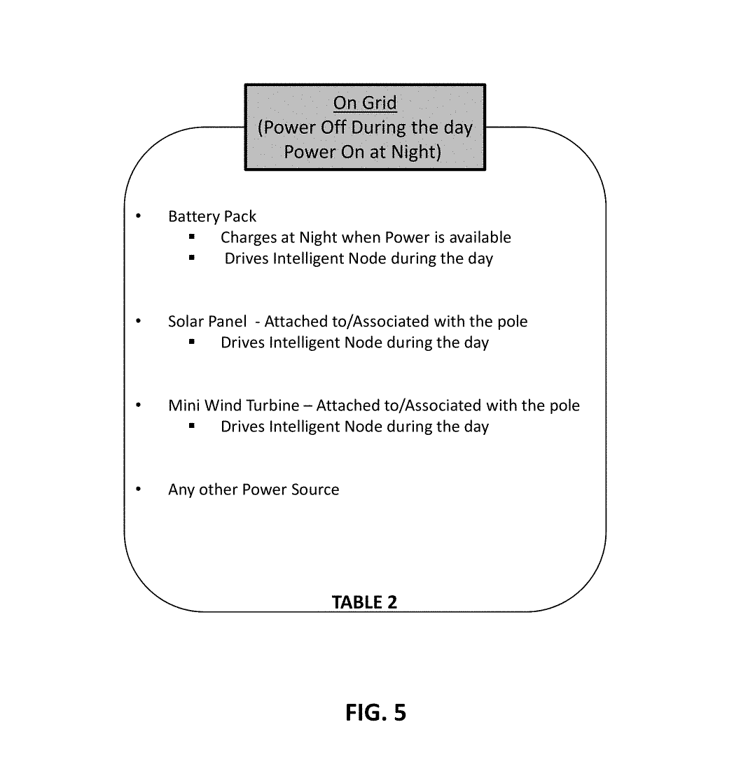

In FIG. 5, Table 2 depicts an on grid scenario, slightly more problematic than Table 1 of FIG. for. In Table 2, AC power is supplied to the pole 104. More specifically, in Table 1 the lighting fixture 304 is connected to the power grid so that AC line power is available at night to energize the LEDs and provide illumination. However, as noted above, the AC power is turned off during the day.

In Table 2, the batteries can be charged at night when AC power is supplied to the pole 104. Operation of the lighting fixture 304 is irrelevant to operation of the embodiments, and the lights do not need to be powered for embodiments of the invention to operate. However, when the AC power is supplied to the pole 104 at night, this AC power can be used to charge the batteries, and/or to power the node 306. Once charged, the batteries can drive the intelligent node 306 during the day.

In an alternative arrangement, the batteries may also continue to drive the node 306 at night, as a means of decreasing dependency and costs associated with use of the AC line power. A wind turbine can also be attached to, or associated with, the pole 104. Though a mini wind turbine is depicted in Tables 1 and 2, any alternative energy generation source could be used that could provide similar functionality.

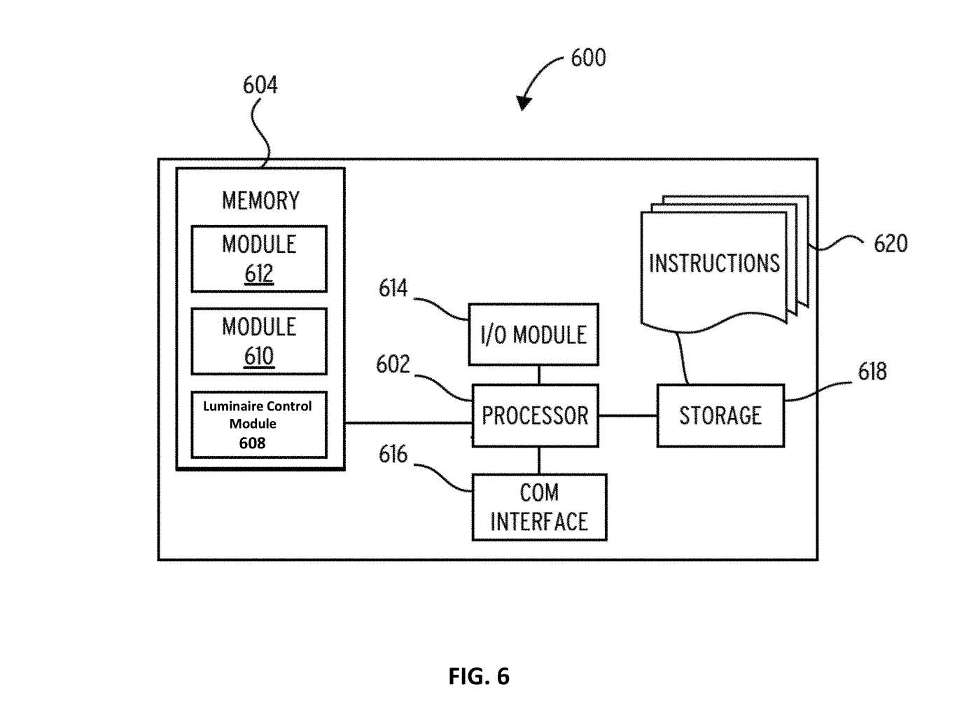

FIG. 6 illustrates a computer system 600, including a processor, according to the embodiments. The controller 600 can include a processor 602 having a specific structure. The specific structure can be imparted to the processor 602 by instructions stored in a memory 604 and/or by instructions 620 fetchable by the processor 602 from a storage medium 618. The storage medium 618 may be co-located with the controller 600 as shown, or it can be remote and communicatively coupled to the controller 600. Such communications can be encrypted.

The controller 600 can be a stand-alone programmable system, or a programmable module included in a larger system. For example, the controller 600 can be included in the node 306 described previously.

The controller 600 may include one or more hardware and/or software components configured to fetch, decode, execute, store, analyze, distribute, evaluate, and/or categorize information. Furthermore, controller 600 includes an input/output (I/O) module 614.

The processor 602 may include one or more processing devices or cores (not shown). In some embodiments, the processor 602 may be a plurality of processors, each having either one or more cores. The processor 602 can execute instructions fetched from the memory 604, i.e. from one of memory modules 612, 610, or 608. Alternatively, the instructions can be fetched from the storage medium 618, or from a remote device connected to the controller 600 via a communication interface 616.

Without loss of generality, the storage medium 618 and/or the memory 604 can include a volatile or non-volatile, magnetic, semiconductor, tape, optical, removable, non-removable, read-only, random-access, or any type of non-transitory computer-readable computer medium. The storage medium 618 and/or the memory 604 may include programs and/or other information usable by processor 602.

By way of example, the memory module 608 can be a luminaire control module, and can include instructions that, when executed by the processor 602, cause the processor 602 to perform certain operations to control the luminaire control module, or it node controller. The operations can include online monitoring of luminaire data, such as lumen output, calibration data, power delivery, metering data, ON & OFF schedules, maintenance records, location data, etc. The operations can also include performing one or more of the advanced functions associated with a microphone, a camera, sensors etc. Generally, the operations can include any tasks, operations, and/or steps described previously in the context of FIGS. 1-5.

Those skilled in the relevant art(s) will appreciate that various adaptations and modifications of the embodiments described above can be configured without departing from the scope and spirit of the disclosure. Therefore, it is to be understood that, within the scope of the appended claims, the disclosure may be practiced other than as specifically described herein.

What is claimed is:

1. A control system electrically coupled to a luminaire, comprising:
a processor for facilitating (i) luminaire control and (ii) performance of a number of advanced functions; and
wherein the processor is configured to receive power from at least two power sources; and
wherein one of the power sources is configured to provide power responsive to power provided by the other power source.

2. The control system of claim 1, wherein the number of advanced functions is responsive to the provided power.

3. The control system of claim 2, wherein the number of advanced functions is responsive to a level of the provided power.

4. The control system of claim 1, wherein the other power source includes power from a power grid; and
wherein the one power source includes at least one of solar, wind, and a battery.

5. The control system of claim 4, further comprising a utility meter for measuring the provided power.

6. The control system of claim 1, wherein the one power source is configured to provide power responsive to a level of the power provided by the other power source.

7. A non-transitory computer-readable storage medium for use with a control system electrically coupled to a luminaire, the computer-readable storage medium including instructions that when executed by a processor, cause the processor to perform operations comprising:
receiving, in a node controller within the control system, power from a first power source; and
receiving, in the node, power from a second power source when power from the first power source reaches a threshold.

8. The computer-readable storage medium of claim 7, wherein the node controller facilitates (i) luminaire control and (ii) performance of a number of advanced functions.

9. The computer-readable storage medium of claim 8, wherein the number of advanced functions is responsive to the provided power.

10. The computer-readable storage medium of claim 7, wherein the other power source includes power from a power grid; and
wherein the one power source includes at least one of solar, wind, and a battery.

11. The computer-readable storage medium of claim 7 further comprising a utility meter for measuring the provided power.

12. The computer-readable storage medium of claim 7, wherein the one power source is configured to provide power responsive to a level of the power provided by the other power source.

13. A method for providing auxiliary power via a control system electrically coupled to a luminaire, comprising:
receiving, in a node controller within the control system, power from a first power source; and
receiving, in the node, power from a second power source when power from the first power source reaches a threshold.

14. The method of claim 13, wherein the node controller facilitates (i) luminaire control and (ii) performance of a number of advanced functions.

15. The computer-readable storage medium of claim 14, wherein the number of advanced functions is responsive to the provided power.

16. The computer-readable storage medium of claim 13, wherein the other power source includes power from a power grid; and
wherein the one power source includes at least one from the group including solar, wind, and a battery.

17. The computer-readable storage medium of claim 13, wherein the one power source is configured to provide power responsive to a level of the power provided by the other power source.
